(19) United States
(12) Patent Application Publication
(10) Pub. No.: US 2002/0084451 A1
(43) Pub. Date: Jul. 4, 2002

(54) Silicon wafers substantially free of oxidation induced stacking faults

(76) Inventors: Thomas C. Mohr, St. Charles, MO (US); Luciano Mule' Stagno, St. Louis, MO (US); Lu Fei, St. Louis, MO (US); Mohsen Banan, Grover, MO (US); Antonella Brianza, Novara (IT)

Correspondence Address: SENNIGER POWERS LEAVITT AND ROEDEL, ONE METROPOLITAN SQUARE, 16TH FLOOR, ST LOUIS, MO, 63102, US

(21) Appl. No.: 10/046,029

(22) Filed: Nov. 7, 2001

Related U.S. Application Data
(60) Provisional application No. 60/259,000, filed on Dec. 29, 2000.

(51) Int. Cl. H01L 47/00

(52) U.S. Cl. 257/1

(57) ABSTRACT

The present invention is directed to an epitaxial silicon wafer, as well as to a process for the preparation thereof, wherein the substrate wafer is highly P-doped, has silicon lattice vacancies as the predominant intrinsic point defect and is substantially free of oxidation induced stacking faults and the epitaxial silicon layer grown on the substrate wafer is substantially free of grown in oxidation induced stacking faults.

### CROSS-REFERENCE TO RELATED APPLICATIONS

This application claims the benefit of U.S. Provisional Application No. 60/259,000, filed Dec. 29, 2000.

### BACKGROUND OF THE INVENTION

The present invention relates generally to epitaxial silicon wafers. More particularly, the present invention relates to epitaxial silicon wafers, as well as to a process for the preparation thereof, wherein the substrate wafers are highly P-doped, having silicon lattice vacancies as the predominant intrinsic point defect and being substantially free of oxidation induced stacking faults.

Single crystal silicon, from which a single crystal silicon wafer may be obtained, is commonly prepared by the so-called Czochralski (“Cz”) method. In this method, polycrystalline silicon (“polysilicon”) is charged to a crucible and melted, a seed crystal is brought into contact with the molten silicon and a single crystal is grown by slow extraction. After formation of a neck is complete, the diameter of the crystal is enlarged by decreasing the pulling rate and/or the melt temperature until the desired or target diameter is reached. The cylindrical main body of the crystal which has an approximately constant diameter is then grown by controlling the pull rate and the melt temperature while compensating for the decreasing melt level. Near the end of the growth process but before the crucible is emptied of molten silicon, the crystal diameter must be reduced gradually to form an end-cone. Typically, the end-cone is formed by increasing the crystal pull rate and heat supplied to the crucible. When the diameter becomes small enough, the crystal is then separated from the melt.

In recent years, it has been recognized that a number of defects in single crystal silicon form in the crystal growth chamber as the crystal cools after solidification. Such defects arise, in part, due to the presence of an excess (i.e. a concentration above the solubility limit) of intrinsic point defects, which are known as vacancies and self-interstitials. Silicon crystals grown from a melt are typically grown with an excess of one or the other type of intrinsic point defect, either crystal lattice vacancies (“V”) or silicon self-interstitials (“I”) I. It has been suggested that the type and initial concentration of these point defects in the silicon are determined at the time of solidification and, if these concentrations reach a level of critical supersaturation in the system and the mobility of the point defects is sufficiently high, a reaction, or an agglomeration event, will likely occur. Agglomerated intrinsic point defects in silicon can severely impact the yield potential of the material in the production of complex and highly integrated circuits.

Vacancy-type defects are recognized to be the origin of such observable crystal defects as D-defects, Flow Pattern Defects (FPDs), Gate Oxide Integrity (GOI) Defects, Crystal Originated Particle (COP) Defects, crystal originated Light Point Defects (LPDs), as well as certain classes of bulk defects observed by infrared light scattering techniques such as Scanning Infrared Microscopy and Laser Scanning Tomography. Also present in regions of excess vacancies, just inside the V/I boundary, are defects which act as the nuclei for ring oxidation induced stacking faults (OISF). It is speculated that this particular defect is a high temperature nucleated oxygen agglomerate catalyzed by the presence of excess vacancies.

Defects relating to self-interstitials are less well studied. They are generally regarded as being low densities of interstitial-type dislocation loops or networks. Such defects are not responsible for gate oxide integrity failures, an important wafer performance criterion, but they are widely recognized to be the cause of other types of device failures usually associated with current leakage problems.

Epitaxial silicon growth typically involves a chemical vapor deposition process wherein a substrate, such as a single crystal silicon wafer, is heated while a gaseous silicon compound is passed over the wafer surface to effect pyrolysis or decomposition. When a single crystal silicon wafer is used as the substrate, the silicon is deposited in such a way as to continue the growth of the single crystal structure. As a result, defects present on the substrate surface, such as agglomerated silicon self-interstitial defects and OISF, may directly impact the quality of the resulting epitaxial wafer. This impact on quality is due to the fact that, by continuing the growth of the single crystal structure, defects present on the substrate surface may continue growth, resulting in the formation of new crystal defects, i.e. grown-in defects, in the epitaxial layer. For example, epitaxial defects such as mounds, epitaxial stacking faults and hillocks, having a maximum cross-sectional width ranging from the current detection limit of a laser-based auto-inspection device of about 0.1 microns to greater than about 10 microns, can be formed.

To date, one approach to avoiding many of the causes of grown-in defects has been to grow the silicon ingot, from which the substrate wafer is obtained, at a high rate in an attempt to cause the ingot to be “vacancy dominated” (i.e., silicon wherein vacancies are the predominant intrinsic point defect). This approach has been pursued because it is generally believed that agglomerated vacancy defects, or “voids,” at the surface of the substrate will be effectively filled or covered by the silicon deposited during the epitaxial deposition process. However, the introduction of a dopant atoms (e.g., boron) into the silicon melt are known to reduce the concentration of vacancies incorporated in the crystal during the growth process resulting in a decrease of the diameter of the vacancy-dominated region of the crystal (see, e.g., M. Suhren et al., “Crystal Defects in Highly Boron Doped Silicon.” Electrochemical Society Proceedings, Vol. 96-13, pp. 132-139, 1996).

Accordingly, a need continues to exist for a process which enables a doped single crystal silicon ingot to be grown, some portion or segment of which is predominantly vacancy dominated and substantially free of an OISF ring. Such an ingot segment would yield substrate wafers particularly suited for epitaxial deposition.

### SUMMARY OF THE INVENTION

Among the objects and features of the present invention, therefore, is the provision of an epitaxial silicon wafer wherein the epitaxial layer is substantially free of defects associates with oxidation induced stacking faults; the provision of such a wafer wherein the substrate is a p-doped single crystal silicon wafer; the provision of such a substrate wafer wherein vacancies are the predominant intrinsic point defect; and, the provision of such a substrate wafer which is substantially free of oxidation induced stacking faults. Further among the objects and features of the present invention is the provision of a process for preparing a single crystal silicon ingot, from which such a substrate wafer is obtained.

Briefly, therefore, the present invention is directed to a single crystal silicon wafer, the wafer characterized by a diameter of at least about 150 mm, a resistivity that is less than about 0.03 Ω·cm, being vacancy-dominated and being substantially free oxidation induced stacking faults.

The present invention is further directed to an epitaxial wafer comprising a single crystal silicon substrate that has a diameter of at least about 150 mm, a resistivity that is less than about 0.03 Ω·cm, which is vacancy-dominated and substantially free of oxidation induced stacking faults and an epitaxial layer deposited upon a surface of the substrate, the epitaxial layer being substantially free of grown-in defects.

The present invention is also directed to a single crystal silicon ingot having a central axis, a seed-cone, an end-cone, and a constant diameter portion between the seed-cone and the end-cone having a circumferential edge and a radius extending at least about 75 mm from the central axis to the circumferential edge, the single crystal silicon ingot being characterized in that after the ingot is grown and cooled from the solidification temperature, the constant diameter portion contains a generally cylindrical region that has a resistivity that is less than about 0.03 Ω·cm, is vacancy-dominated and is substantially free of oxidation induced stacking faults wherein the generally cylindrical region has a width equal to that of the constant diameter portion of the ingot and has a length, measured along the central axis, of at least about 20% of the length of the constant diameter portion of the ingot.

Additionally, the present invention is directed to a process for growing a single crystal silicon ingot in which the ingot comprises a central axis, a seed-cone, an end-cone and a constant diameter portion between the seed-cone and the end-cone having a circumferential edge and a radius of at least about 75 mm extending from the central axis to the circumferential edge, the ingot having a resistivity less than about 0.03 Ω·cm, the ingot being grown from a silicon melt and then cooled from the solidification temperature in accordance with the Czochralski method. Specifically, the process comprises controlling a growth velocity, v, and an average axial temperature gradient, G₀, during the growth of the constant diameter portion of the crystal over the temperature range from solidification to a temperature of no less than about 1325° C., to cause the formation of an generally cylindrical region in which vacancies, upon cooling of the ingot from the solidification temperature, are the predominant intrinsic point defect and the generally cylindrical region has a width equal to that of constant diameter portion of the ingot.

Other objects will be in part apparent and in part pointed out hereinafter.

### BRIEF DESCRIPTION OF THE DRAWINGS

FIG. 1 is a graph which shows an example of how the initial concentration of self-interstitials, [I], and vacancies, [V], changes with an increase in the value of the ratio v/G₀, where v is the growth rate and G₀ is the average axial temperature gradient.

FIG. 2 is graph which shows an example of how the initial concentration of self-interstitials, [I], and vacancies, [V], can change along the radius of an ingot or wafer, as the value of the ratio v/G₀ decreases, due to an increase in the value of G₀. Note that at the V/I boundary a transition occurs from vacancy dominated material to self-interstitial dominated material.

FIG. 3 is a top plan view of a single crystal ingot or wafer showing regions of vacancy, V, and self-interstitial, I, dominated materials respectively, as well as the V/I boundary that exists between them.

FIG. 4 is a longitudinal, cross-sectional view of a single crystal silicon ingot, in detail, an axially symmetric region of a constant diameter portion of the ingot.

### DETAILED DESCRIPTION OF THE INVENTION

It has recently been discovered that the presence of oxidation induced stacking faults at the surface of a single crystal silicon substrate wafer, upon which an epitaxial layer is deposited, are one cause of grown-in defect formation in the epitaxial layer. It is therefore desirable to utilize substrate wafers which are substantially free of such faults for the preparation of epitaxial wafers, particularly highly P-doped silicon wafers.

It is to be noted that, as used herein, the terms “P-type” or “P-doped” refers to silicon containing an element from Group 3 of the periodic Table such as boron, aluminum, gallium and indium, most typically boron. A P-type wafer typically has a resistivity from about 100 Ω·cm (ohm centimeters) to about 0.005 Ω·cm. For silicon doped with boron, the foregoing resistivity values correspond to a dopant concentration of about 3×10¹⁷ atoms/cm³ to about 3×10⁹ atoms/cm³, respectively. P-type wafers are typically further characterized based on resistivity, for example, a P-type wafer having a resistivity of about 20 Ω·cm (about 4×10¹⁸ boron atoms/cm³) to about 1 Ω·cm is generally referred to as P-silicon. A P-type wafer having a resistivity of about 0.03 Ω·cm to about 0.01 Ω·cm is generally referred to as P⁺-silicon. A wafer having a resistivity of about 0.01 Ω·cm (about 1×10¹⁹ boron atoms/cm³) to about 0.005 Ω·cm (about 3×10¹⁹ boron atoms/cm³) is generally referred to as P⁺⁺-silicon. For purposes of the present invention, P⁺and P⁺⁺-silicon are considered “highly P-doped silicon.”

One approach to eliminating the presence of oxidation induced stacking faults, or the OISF ring, in silicon wafers is to control the growth conditions of a single crystal silicon ingot, from which the wafers are obtained, such that (i) silicon self-interstitials are the predominant intrinsic point defects and (ii) the ingot is substantially free of agglomerated interstitial defects (see, e.g., PCT/US98/07365, PCT/US98/07305 and PCT/US99/24067, which are incorporated herein by reference). Growth of the silicon ingot under such conditions effectively results in the “collapse” of the OISF ring into the center of the ingot.

Alternatively, the single crystal silicon ingot may be grown under conditions which effectively push or extend the OISF ring out to the circumferential edge of the ingot. This can typically be achieved by simply growing the ingot at a high rate, such that vacancies are the predominant intrinsic point defect. The presence of such defects is not believed to be narrowly critical, because the epitaxial deposition process acts to fill any pits or voids present at the wafer surface caused by these vacancies. However, as ingot diameters continue to increase, achieving and/or maintaining a growth rate over a significant portion of the ingot main body, such that the OISF ring is not present, can be difficult if not impossible. Additionally, it is known that the introduction of P-type dopants to the silicon melt, particularly highly P-doped silicon, further complicates matters, making it even more difficult to eliminate the OISF ring from large diameter (i.e., 150 mm, 200 mm, 250 mm, 300 mm or more) crystals.

Accordingly, it has now been discovered that the formation of an epitaxial silicon wafer having an epitaxial layer which is substantially free of grown-in defects, caused by the presence of oxidation induced stacking faults at the surface of a highly P-doped substrate upon which the epitaxial layer is deposited, can be achieved by using as the substrate a highly P-doped single crystal silicon wafer which is substantially free of such defects. These “OISF-free” substrate wafers are obtained or sliced from a single crystal silicon ingot, having a diameter of 150 mm or more, which is grown from a highly p-doped silicon melt under conditions which ensure (i) vacancies are the predominant intrinsic point defect in the ingot and (ii) the ingot is substantially free of oxidation induced stacking faults. As used herein, substantially free of oxidation induced stacking faults describes silicon: (a) that has no discernable ring of oxidation induced stacking faults which when subjected to the methods of visually detecting agglomerated defects set forth below; or (b) that has a concentration of oxidation induced stacking faults that is less than about 10 per cm² when inspected with a laser-based auto-inspection device set to detect a maximum cross-sectional width ranging from about 0.1 microns to greater than about 10 microns.

As further described herein, the growth of such a silicon ingot is achieved by means of controlling, in combination, the growth velocity, v, as well as the average axial temperature gradient, G₀, during growth of a portion or all of the main body of the ingot.

Substrate

As has previously been reported (see, e.g., PCT/US98/07365, PCT/US98/07305 and PCT/US98/07304, which are incorporated herein by reference), it appears that the type and initial concentration of intrinsic point defects, such as silicon lattice vacancies or silicon self-interstitials, in single crystal silicon wafers are initially determined as the ingot, from which these wafers are obtained, cools from the temperature of solidification (i.e., about 1410° C.) to a temperature greater than 1300° C. (i.e., at least about 1325° C., at least about 1350° C. or even at least about 1375° C.); that is, the type and initial concentration of these defects are controlled by the ratio v/G₀, where v is the growth velocity and G₀ is the average axial temperature gradient over this temperature range.

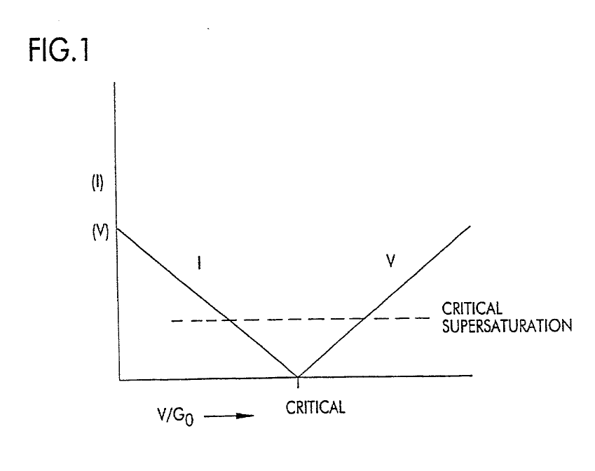

Referring now to FIG. 1, for increasing values of v/G₀, a transition from decreasingly self-interstitial dominated growth to increasingly vacancy dominated growth occurs near a critical value of v/G₀ which, based upon currently available information, appears to be about 2.1×10⁻⁵ cm²/sK, where G⁰ is determined under conditions in which the axial temperature gradient is constant within the temperature range defined above. At this critical value, the concentrations of these intrinsic point defects are at equilibrium. However, as the value of v/G⁰ exceeds the critical value, the concentration of vacancies increases. Likewise, as the value of v/G⁰ falls below the critical value, the concentration of self-interstitials increases. If these concentrations reach a level of critical supersaturation in the system, and if the mobility of the point defects is sufficiently high, a reaction, or an agglomeration event, will likely occur.

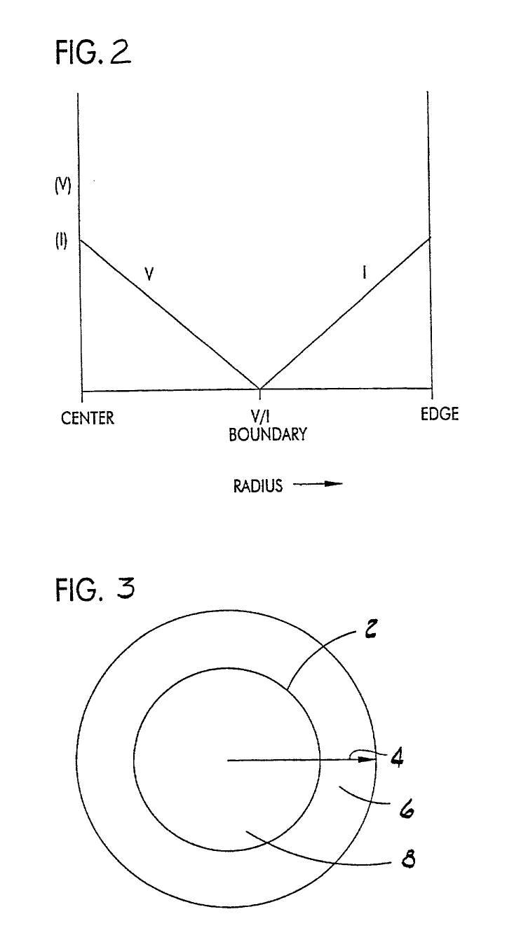

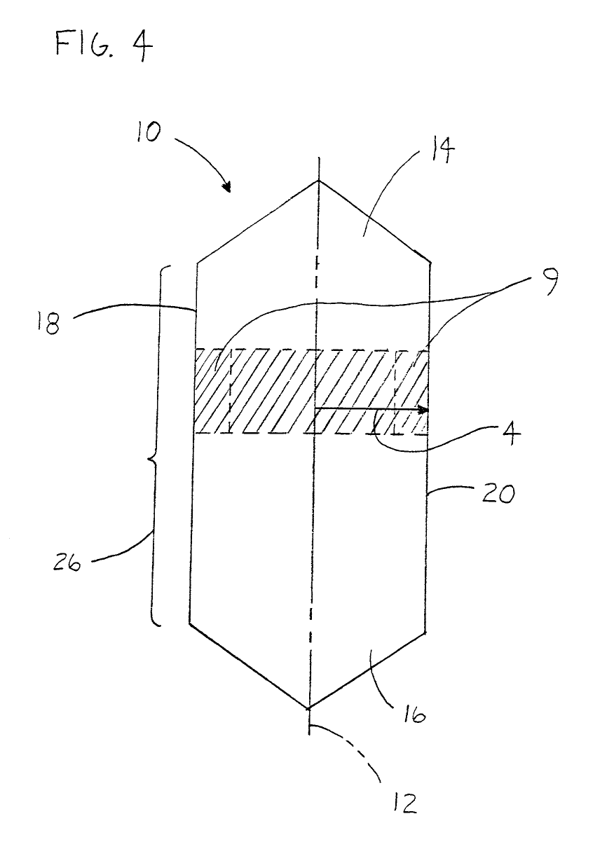

Typically, the average axial temperature gradient, G⁰, increases as a function of increasing radius for single crystal silicon which is grown according to the Czochralski method. This means that the value of v/G⁰ is typically not singular across the radius of an ingot (v/G⁰(r) represents v/G₀ as a function of radial position). As a result of this variation, the type and initial concentration of intrinsic point defects are not constant. If the critical value of v/G₀, denoted in FIGS. 2 and 3 as the V/I boundary 2, is reached at some point along the radius 4 of the ingot, the material will switch from being vacancy dominated to self-interstitial dominated. In addition, the ingot will contain an axially symmetric region of self-interstitial dominated material 6 (in which the initial concentration of silicon self-interstitial atoms increases as a function of increasing radius), surrounding a generally cylindrical region of vacancy dominated material 8 (in which the initial concentration of vacancies decreases as a function of increasing radius).

Oxidation induced stacking faults, which form in the vacancy dominated region of the ingot, are typically concentrated within a ring-like region of varying width just inside the V/I boundary, often referred to as the “P-band.” An epitaxial layer deposited thereon, will have defects in the epitaxial layer result. In the past, these defects were not a concern for electronic circuit manufacturers. The increasing complexity of circuit designs, however, makes the designs more susceptible to intrinsic point defects including oxidation induced stacking faults. Without being held to a particular theory, it is presently believed that dopant atoms interact with, and “neutralize” vacancies by assuming a substitutional position. For boron doped silicon, the neutralization of vacancies begins to shift the V/I boundary inward at concentrations corresponding to about 0.04 Ω·cm to about 0.03 Ω·cm. At boron concentrations corresponding to about 0.01 Ω·cm to about 0.005 Ω·cm, the shift in the V/I boundary is significant.

In accordance with the present invention, it has been discovered that a highly p-doped single crystal silicon ingot, typically having a diameter of at least about 150 mm, can be grown such that at least a segment of the constant diameter portion of the ingot is substantially free of oxidation induced stacking faults by controlling both the growth velocity, v, and the average axial temperature gradient, G₀. Referring now to FIG. 4, a highly P-doped single crystal silicon ingot 10 is grown in accordance with the present process using the Czochralski method. The single crystal silicon ingot comprises a central axis 12, a seed-cone 14, an end-cone 16 and a constant diameter portion 18 between the seed-cone and the end-cone. The constant diameter portion 18 has a circumferential edge 20 and a radius 4 extending from the central axis 12 to the circumferential edge 20. The crystal growth conditions, including growth velocity, v, the average axial temperature gradient, G₀, are controlled not only to cause the formation of a generally cylindrical region of vacancy dominated material 8 that has a width generally corresponding to that of the constant diameter portion 18, but also to cause the formation of such vacancy dominated material which is substantially free of oxidation induced stacking faults. Additionally, the length of this segment is typically at least about 20% of the length of the constant diameter portion 18 of the ingot, and preferably is at least about 40%, more preferably at least about 60%, still more preferably at least about 80%, still more preferably at least about 90%, and most preferably about 100% of the length of the constant diameter portion of the ingot.

Generally speaking, the growth velocity, v, and the average axial temperature gradient, G₀, are typically controlled such that the ratio v/G₀ proximate the circumferential edge, v/G₀(r_{ce}), is at least about equal to or greater than the critical value at which the crystal transitions from vacancy-dominated material to interstitial-dominated material. Based on current information, the v/G₀ is about 2×10⁻⁵ cm²/sK. Preferably, the growth velocity and average axial temperature gradient are controlled such that the ratio v/G₀(r_{ce}) ranges in value from about 1.0 to about 3.0 times the critical value of v/G₀ (i.e., about 2×10⁻⁵ cm²/sK to about 6×10⁻⁵ cm²/sK). More preferably, the ratio v/G ₀(r_{ce}) will range in value from about 2.0 to about 2.75 times the critical value of v/G₀ (i.e., about 4×10⁻⁵ cm²/sK to about 5.5×10⁻⁵ cm²/sK based upon currently available information for the critical value of v/G₀). Most preferably, the ratio v/G₀(r_{ce}) will range in value from about 2.1 to about 2.6 times the critical value of v/G₀ (i.e., about 4.2×10⁻⁵ cm²/sK to about 5.2×10⁻⁵ cm²/sK)

In this regard it is to be noted that because v/G₀ is not singular over the radius of the ingot, typically decreasing along the radius moving from the central axis to the circumferential edge of the ingot, for purposes of the present process it is the value of v/G₀ proximate the circumferential edge (i.e., “v/G₀(r_{ce})”) which matters, because if the value at this point exceeds the critical value then the value at every point along the radius will exceed it as well.

It is to be still further noted that, as mentioned above, for highly p-doped silicon melts, as well as for increasing diameters of the silicon ingot, it can become more difficult to dictate the type of silicon which is formed (i.e., whether it is vacancy or self-interstitial dominated), as well as the general position of the V/I boundary (to ensure the substantial absence of an OISF ring), solely by means of controlling the growth velocity, v. As a result, the ability to dictate or control G₀ is also an important factor of the present invention.

Control of the average axial temperature gradient, G₀, may be achieved through the design of the “hot zone” of the crystal puller, i.e. the graphite (or other materials) that makes up the heater, insulation, heat and radiation shields, among other things. Although the design particulars may vary depending upon the make and model of the crystal puller, in general, G₀ may be controlled using any of the means currently known in the art for controlling heat transfer at the melt/solid interface, including reflectors, radiation shields, purge tubes, light pipes, and heaters. In accordance with the present invention, such means are employed so as to control the thermal conditions, as well as the rate at which the ingot cools, within the crystal puller. More specifically, typically the hot zone will be configured so as to cool the vacancy dominated segment of the ingot, generally over a temperature range bound by the temperature of solidification and about 1000° C., at a rate which (i) typically ranges from about 0.1° C./minute to about 3° C./minute, (ii) preferably from about 0.1° C./minute to about 1.5° C./minute, (iii) more preferably from about 0.1° C./minute to about 1° C./minute, and (iv) still more preferably from about 0.1° C./minute to about 0.5° C./minute.

In general, radial variations in G₀ are minimized by positioning such an apparatus within about one crystal diameter above the melt/solid interface. G₀ can be controlled further by adjusting the position of the apparatus relative to the melt and crystal. This is accomplished either by adjusting the position of the apparatus in the hot zone, or by adjusting the position of the melt surface in the hot zone. In addition, when a heater is employed, G₀ may be further controlled by adjusting the power supplied to the heater. Any, or all, of these methods can be used during a batch Czochralski process in which melt volume is depleted during the process.

It is generally preferred for some embodiments of the present invention that the average axial temperature gradient, G₀, be relatively constant as a function of diameter of the ingot. However, it should be noted that as improvements in hot zone design allow for variations in G₀ to be minimized, mechanical issues associated with maintaining a constant growth rate become an increasingly important factor. This is because the growth process becomes much more sensitive to any variation in the pull rate, which in turn directly effects the growth rate, v. In terms of process control, this means that it is favorable to have values for G₀ which differ over the radius of the ingot, provided of course that the value of v/G₀ remains within the ranges noted above.

In view of the foregoing, the control of G₀ involves a balance between minimizing radial variations in G₀ and maintaining favorable process control conditions. Typically, therefore, the pull rate after about one diameter of the crystal length will range from about 0.7 mm/minute to about 0.85 mm/minute. It is to be noted that the pull rate is dependent upon both the crystal diameter and crystal puller design. The stated ranges are typical for 150 mm diameter crystals. In general, the pull rate will decrease as the crystal diameter increases. However, the crystal puller may be designed to allow pull rates in excess of those stated here. As a result, most preferably the crystal puller will be designed to enable the pull rate to be as fast as possible, in order to maximize throughput of the present P⁺-type, substantially oxidation induced stacking fault free silicon.

The crystal pull rate profile needed to produce a highly P-doped silicon ingot that has a generally cylindrical region of vacancy dominated material 8 with a radius that extends from the central axis 12 to the circumferential edge 20 for a given crystal puller hot zone design may be determined empirically. Generally speaking, this empirical approach involves first obtaining readily available data on the axial temperature profile for an ingot grown in a particular crystal puller, as well as the radial variations in the average axial temperature gradient for an ingot grown in the same puller. Collectively, this data is used to pull one or more single crystal silicon ingots, which are then analyzed for the presence of oxidation induced stacking faults. In this way, an optimum pull rate profile can be determined.

In addition to the radial variations in v/G₀ resulting from an increase in G₀ over the radius of the ingot, v/G₀ may also vary axially as a result of a change in v, or as a result of natural variations in G₀ due to the Czochralski process. For a standard Czochralski process, v is altered as the pull rate is adjusted throughout the growth cycle, in order to maintain the ingot at a constant diameter. These adjustments, or changes, in the pull rate in turn cause v/G₀ to vary over the length of the constant diameter portion of the ingot. Accordingly, it is therefore desirable to control the pull rate in order to prevent the formation of self-interstitials in the ingot. As a result, however, variations in the radius of the ingot may occur. In order to ensure that the resulting ingot has a constant diameter, the ingot is therefore preferably grown to a diameter larger than that which is desired. The ingot is then subjected to processes standard in the art to remove excess material from the surface, thus ensuring that an ingot having a constant diameter portion is obtained.

For vacancy-dominated highly p-doped single crystal silicon produced in accordance with the method of the present invention the concentration of oxygen can be up to about 18 ppma (parts per million atomic, ASTM standard F-121-83). However, the oxygen concentration is typically about 10 ppma to about 16 ppma. In contrast, conventional single crystal silicon has less than about 13 ppma oxygen, preferably less than about 12 ppma oxygen, more preferably less than about 11 ppma oxygen, and most preferably less than about 10 ppma oxygen. Conventionally, a low oxygen content is preferred because, in medium to high oxygen contents wafers (i.e., 14 ppma to 18 ppma), the formation of oxidation induced stacking faults and bands of enhanced oxygen clustering just inside the V/I boundary becomes more pronounced which is detrimental to the epitaxial layer.

The effects of enhanced oxygen clustering may be further reduced by a number of methods, used singularly or in combination. For example, oxygen precipitate nucleation centers typically form in silicon which is annealed at a temperature in the range of about 350° C. to about 750° C. For some applications, therefore, it may be preferred that the crystal be a “short” crystal, that is, a crystal which has been grown in a Czochralski process until the seed end has cooled from the melting point of silicon (about 1410° C.) to about 750° C. after which the ingot is rapidly cooled. In this way, the time spent in the temperature range critical for nucleation center formation is kept to a minimum and the oxygen precipitate nucleation centers have inadequate time to form in the crystal puller.

Preferably, however, oxygen precipitate nucleation centers formed during the growth of the single crystal are dissolved by annealing the single crystal silicon. Provided they have not been subjected to a stabilizing heat-treatment, oxygen precipitate nucleation centers can be annealed out of silicon by rapidly heating the silicon to a temperature of at least about 875° C., and preferably continuing to increase the temperature to at least 1000° C., at least 1100° C., or more. By the time the silicon reaches 1000° C., substantially all (e.g., >99%) of such defects have annealed out. It is important that the wafers be rapidly heated to these temperatures, i.e., that the rate of temperature increase be at least about 10° C. per minute and more preferably at least about 50° C. per minute. Otherwise, some or all of the oxygen precipitate nucleation centers may be stabilized by the heat-treatment. Equilibrium appears to be reached in relatively short periods of time, i.e., on the order of about 60 seconds or less. Accordingly, oxygen precipitate nucleation centers in the single crystal silicon may be dissolved by annealing it at a temperature of at least about 875° C., preferably at least about 950° C., and more preferably at least about 1100° C., for a period of at least about 5 seconds, and preferably at least about 10 minutes.

The dissolution may be carried out in a conventional furnace or in a rapid thermal annealing (RTA) system. The rapid thermal anneal of silicon may be carried out in any of a number of commercially available rapid thermal annealing (“RTA”) furnaces in which wafers are individually heated by banks of high power lamps. RTA furnaces are capable of rapidly heating a silicon wafer, e.g., they are capable of heating a wafer from room temperature to 1200° C. in a few seconds. One such commercially available RTA furnace is the model 610 furnace available from AG Associates (Mountain View, Calif.). In addition, the dissolution may be carried out on silicon ingots or on silicon wafers, preferably wafers.

It is to be noted that, in one alternative embodiment of the present invention, V/G₀ is controlled not only to ensure no V/I boundary exists along the radius for at least a portion of the length of the ingot, such that vacancies are the dominant intrinsic point defect from center to circumferential edge, but also that agglomerated vacancy defects are avoided in this axially symmetric region extending radially inward from the circumferential edge of the ingot principally by controlling V/G₀. That is, the growth conditions are controlled not only so that v/G₀ has a value greater than the critical value of v/G₀ for p⁺doped silicon, but also that no agglomerated vacancy defects are formed (such as, for example, by means of the process disclosed in U.S. Pat. No. 5,919,302, which is incorporated herein by reference).

Epitaxial Layer

An epitaxial layer may be deposited or grown on a surface of the above-described substrate by means known in the art. (See, e.g., U.S. Pat. No. 5,789,309.) Typically, growth of the epitaxial layer is achieved by chemical vapor deposition because this is one of the most flexible and cost efficient methods for growing epitaxial layers on semiconductor material. Generally speaking, chemical vapor deposition involves the introduction of volatile reactants (e.g., SiCl₄, SiHCl₃, SiH₂Cl₂ or SiH₄) with a carrier gas (usually hydrogen) into an epitaxial reactor. Although process conditions may vary, in the case of monocrystalline layer deposition the temperature will generally range between 1080° C. and 1150° C. In addition, the environment in which the deposition occurs is preferably clean (i.e., free of particulate contaminants) and has an oxygen content below about 1 PPMA.

In accordance with the present invention, experience to-date suggests that it is desirable to utilize a single crystal silicon substrate which is substantially free of oxidation induced stacking faults. Such a substrate is desirable because, during deposition, silicon material being deposited on the wafer surface tends to accumulate more rapidly at the sites of these stacking faults, as compared to the flat surface surrounding them. The deposition and accumulation of silicon material at these defect sites results in the formation of grown-in defects, i.e. hillocks or stacking faults, within the epitaxial layer. Of particular concern are large area grown-in defects which have a diameter greater than or equal to about 10 microns, as measured by laser beam surface scanning equipment common in the art (see, e.g., Tencor 6200 series laser scanners, such as model 6220, commercially available from Tencor Inc. of Mountain View, Calif.).

Without being held to any particular theory, it is generally believed that defects in the epitaxial layer may result from a number of different causes. For example, particulate and other organic contaminants present on the substrate surface may, along with oxidation induced stacking faults, act as sites for silicon material to accumulate during deposition. Accordingly, the present invention may be utilized in conjunction with other means, such as improved methods of substrate cleaning and handling, in an effort to fully eliminate defects within the epitaxial layer. However, if employed alone, the present invention effectively acts to eliminate a significant cause of epitaxial layer defects and, therefore, reduces the overall concentration of such defects.

Furthermore, it is also generally believed that the presence of agglomerated vacancy defects, also referred to as voids, at the surface of the substrate is not narrowly critical to the production of an epitaxial layer which is substantially free of grown-in defects. Rather, it is believed that as silicon material is deposited upon the substrate surface these voids are effectively covered or “filled.” As a result, agglomerated vacancy defects are not propagated through the epitaxial layer. However, to ensure voids or “pits” are not present in the epitaxial layer surface, the epitaxial layer will generally have a thickness sufficient to cover the agglomerated vacancy defects present on the surface of the substrate, the thickness increasing as the size or depth of such defects increases. Typically, the thickness of the layer ranges from at least about 1 micron up to about 15 microns or more. Preferably, the epitaxial layer will have a thickness ranging from about 1 to about 10 microns, more preferably from about 1 to about 8 microns, and most preferably from about 1 to about 4. In this regard it is to be noted that a thinner layer is preferred, provided agglomerated vacancy defects are effectively covered, because it acts to reduce the cost of the resulting epitaxial wafer.

It is to be noted that the present invention is advantageous in that a set of epitaxial wafers may be prepared and assembled using a sequence of substrates obtained from a single ingot, prepared in accordance with the present process. Stated another way, the present invention is advantageous because of the consistency and reliability of the process. The set of epitaxial wafers can be prepared and assembled from a set of substrates which have essentially been obtained sequentially from a single ingot. Therefore, a time consuming inspection process is not necessary in order to identify a substrate suitable (i.e., one substantially free of agglomerated interstitial defects) prior to epitaxial deposition. Likewise, because of the quality of the substrates being employed, a time consuming inspection process is not necessary in order to identify epitaxial wafers which are substantially free of these grown-in defects and, thus, is suitable for inclusion within a set.

The set of epitaxial wafers may be assembled, for example, in a wafer cassette of the type in which wafers are typically stored and shipped, in a boat of the type which are typically used for heat-treating silicon wafers, or in an equivalent wafer carrier. Wafers may be assembled in sets of 5, 10, 20, 25, 50 or more. Typically, however, wafers having diameters up to about 200 mm are currently assembled in sets of 25, while wafers having diameters of about 300 mm or more are currently assembled in sets of 13.

Visual Detection of Agglomerated Defects

Agglomerated defects may be detected by a number of different techniques. For example, flow pattern defects, or D-defects, are typically detected by preferentially etching the single crystal silicon sample in a Secco etch solution for about 30 minutes, and then subjecting the sample to microscopic inspection. (see, e.g., H. Yamagishi et al., Semicond. Sci. Technol. 7, A135 (1992)). Although standard for the detection of agglomerated vacancy defects, this process may also be used to detect agglomerated interstitial defects. When this technique is used, such defects appear as large pits on the surface of the sample when present.

Agglomerated defects may also be detected using laser scattering techniques, such as laser scattering tomography, which typically have a lower defect density detection limit that other etching techniques.

Additionally, agglomerated intrinsic point defects may be visually detected by decorating these defects with a metal capable of diffusing into the single crystal silicon matrix upon the application of heat. Specifically, single crystal silicon samples, such as wafers, slugs or slabs, may be visually inspected for the presence of such defects by first coating a surface of the sample with a composition containing a metal capable of decorating these defects, such as a concentrated solution of copper nitrate. The coated sample is then heated to a temperature between about 900° C. and about 1000° C. for about 5 minutes to about 15 minutes in order to diffuse the metal into the sample. The heat treated sample is then cooled to room temperature, thus causing the metal to become critically supersaturated and precipitate at sites within the sample matrix at which defects are present.

After cooling, the sample is first subjected to a non-defect delineating etch, in order to remove surface residue and precipitants, by treating the sample with a bright etch solution for about 8 to about 12 minutes. A typical bright etch solution comprises about 55 percent nitric acid (70% solution by weight), about 20 percent hydrofluoric acid (49% solution by weight), and about 25 percent hydrochloric acid (concentrated solution).

The sample is then rinsed with deionized water and subjected to a second etching step by immersing the sample in, or treating it with, a Secco or Wright etch solution for about 35 to about 55 minutes. Typically, the sample will be etched using a Secco etch solution comprising about a 1:2 ratio of 0.15 M potassium dichromate and hydrofluoric acid (49% solution by weight). This etching step acts to reveal, or delineate, agglomerated defects which may be present.

In general, regions of interstitial and vacancy dominated material free of agglomerated defects can be distinguished from each other and from material containing agglomerated defects by the copper decoration technique described above. Regions of defect-free interstitial dominated material contain no decorated features revealed by the etching whereas regions of defect-free vacancy dominated material (prior to a high-temperature oxygen nuclei dissolution treatment as described above) contain small etch pits due to copper decoration of the oxygen nuclei.

Further, oxidation induced stacking faults may be visually detected on the surface of a silicon wafer substrate or epitaxial silicon wafer by wet oxidizing the silicon. Specifically, the silicon is wet oxidized for about 2.5 hours at about 1150° C. The wet oxidation creates an oxide layer of about 2 μm thick on the wafer surface. The oxide layer is stripped from the silicon surface using a Wright etch. The wafer is rinsed, dried and then viewed under a microscope for the presence of a ring of oxidation induced stacking faults or is inspected using a laser-based surface inspector.

In view of the above, it will be seen that the several objects of the invention are achieved.

As various changes could be made in the above compositions and processes without departing from the scope of the invention, it is intended that all matter contained in the above description be interpreted as illustrative and not in a limiting sense.

What is claimed is:

1. A single crystal silicon wafer, the wafer characterized by a diameter of at least about 150 mm, a resistivity that is less than about 0.03 Ω·cm, being vacancy-dominated and being substantially free oxidation induced stacking faults.

2. The single crystal silicon wafer as set forth in claim 1 wherein the resistivity is about 0.03 Ω·cm to about 0.01 Ω·cm.

3. The single crystal silicon wafer as set forth in claim 1 wherein the resistivity is about 0.01 Ω·cm to about 0.005 Ω·cm.

4. The single crystal silicon wafer as set forth in claim 1 wherein the wafer has a concentration of oxygen of up to about 18 ppma.

5. The single crystal silicon wafer as set forth in claim 1 wherein the wafer has a concentration of oxygen of about 10 ppma to about 16 ppma.

6. The single crystal silicon wafer as set forth in claim 1 wherein the diameter is about 200 mm.

7. The single crystal silicon wafer as set forth in claim 1 wherein the diameter is about 300 mm.

8. The single crystal silicon wafer as set forth in claim 1 wherein the wafer comprises dopant atoms selected from the group consisting of boron, aluminum, gallium and indium.

9. The single crystal wafer as set forth in claim 1 wherein the wafer comprises boron atoms.

10. The single crystal wafer as set forth in claim 9 wherein the concentration of boron atoms is about 1×10¹⁹ atoms/cm³ to about 3×10¹⁹ atoms/cm³.

11. An epitaxial wafer comprising:
a single crystal silicon substrate that has a diameter of at least about 150 mm, a resistivity that is less than about 0.03 Ω·cm, which is vacancy-dominated and substantially free of oxidation induced stacking faults; and,
an epitaxial layer deposited upon a surface of the substrate, the epitaxial layer being substantially free of grown-in defects.

12. The epitaxial wafer as set forth in claim 11 wherein the epitaxial layer has a thickness of about 1 to about 15 microns.

13. The epitaxial wafer as set forth in claim 11 wherein the epitaxial layer has a thickness of about 1 to about 10 microns.

14. The epitaxial wafer as set forth in claim 11 wherein the epitaxial layer has a thickness of about 1 to about 5 microns.

15. The epitaxial wafer as set forth in claim 11 wherein the diameter of the single crystal silicon substrate is about 200 mm.

16. The epitaxial wafer as set forth in claim 11 wherein the diameter of the single crystal silicon substrate is about 300 mm.

17. The epitaxial wafer as set forth in claim 11 wherein the epitaxial layer has a resistivity of about 100 Ω·cm to about 0.005 Ω·cm.

18. The epitaxial wafer as set forth in claim 11 wherein the epitaxial layer has a resistivity of about 20 Ω·cm to about 1 Ω·cm.

19. The epitaxial wafer as set forth in claim 11 wherein the epitaxial layer has a resistivity of about 0.03 Ω·cm to about 0.01 Ω·cm.

20. The epitaxial wafer as set forth in claim 11 wherein the epitaxial layer has a resistivity of about 0.01 Ω·cm to about 0.005 Ω·cm.

21. The epitaxial wafer as set forth in claim 11 wherein the single crystal silicon substrate and the epitaxial layer comprise dopant atoms selected from the group consisting of boron, aluminum, gallium and indium.

22. The epitaxial wafer as set forth in claim 11 wherein the single crystal silicon substrate and the epitaxial layer comprise boron atoms.

23. The epitaxial wafer as set forth in claim 22 wherein the concentration of boron atoms in the single crystal silicon substrate is about 1×10¹⁹ atoms/cm³ to about 3×10¹⁹ atoms/cm³.

24. The epitaxial wafer as set forth in claim 22 wherein the concentration of boron atoms in the epitaxial layer is about 3×10¹⁷ atoms/cm³ to about 3×10¹⁹ atoms/cm³.

25. The epitaxial wafer as set forth in claim 22 wherein the concentration of boron atoms in the epitaxial layer is about 1×10¹⁹ atoms/cm³ to about 3×10¹⁹ atoms/cm³.

26. A single crystal silicon ingot having a central axis, a seed-cone, an end-cone, and a constant diameter portion between the seed-cone and the end-cone having a circumferential edge and a radius extending at least about 75 mm from the central axis to the circumferential edge, the single crystal silicon ingot being characterized in that after the ingot is grown and cooled from the solidification temperature, the constant diameter portion contains a generally cylindrical region that has a resistivity that is less than about 0.03 Ω·cm, is vacancy-dominated and is substantially free of oxidation induced stacking faults wherein the generally cylindrical region has a width equal to that of the constant diameter portion of the ingot and has a length, measured along the central axis, of at least about 20% of the length of the constant diameter portion of the ingot.

27. The single crystal silicon ingot as set forth in claim 26 wherein the radius of the constant diameter portion is at least about 100 mm.

28. The single crystal silicon ingot as set forth in claim 26 wherein the radius of the constant diameter portion is at least about 150 mm.

29. The single crystal silicon ingot as set forth in claim 26 wherein the length of the generally cylindrical region is at least about 40% of the length of the constant diameter portion of the ingot.

30. The single crystal silicon ingot as set forth in claim 26 wherein the length of the generally cylindrical region is at least about 60% of the length of the constant diameter portion of the ingot.

31. The single crystal silicon ingot as set forth in claim 26 wherein the length of the generally cylindrical region is at least about 80% of the length of the constant diameter portion of the ingot.

32. The single crystal silicon ingot as set forth in claim 26 wherein the length of the generally cylindrical region is about 100% of the length of the constant diameter portion of the ingot.

33. The single crystal silicon ingot as set forth in claim 26 wherein the generally cylindrical region has a concentration of oxygen of up to about 18 ppma.

34. The single crystal silicon ingot as set forth in claim 26 wherein the generally cylindrical region has a concentration of oxygen of about 10 ppma to about 16 ppma.

35. The single crystal silicon ingot as set forth in claim 26 wherein the generally cylindrical region has a resistivity of about 0.03 Ω·cm to about 0.01 Ω·cm.

36. The single crystal silicon ingot as set forth in claim 26 wherein the generally cylindrical region has a resistivity of about 0.01 Ω·cm to about 0.005 Ω·cm.

37. The single crystal silicon ingot as set forth in claim 26 wherein the ingot comprises dopant atoms selected from the group consisting of boron, aluminum, gallium and indium.

38. The single crystal silicon ingot as set forth in claim 26 wherein the ingot comprises boron atoms.

39. The single crystal silicon ingot as set forth in claim 38 wherein the concentration of boron atoms is about 1×10¹⁹ atoms/cm³ to about 3×10¹⁹ atoms/cm³.

40. A process for growing a single crystal silicon ingot in which the ingot comprises a central axis, a seed-cone, an end-cone and a constant diameter portion between the seed-cone and the end-cone having a circumferential edge and a radius of at least about 75 mm extending from the central axis to the circumferential edge, the ingot having a resistivity less than about 0.03 Ω·cm, the ingot being grown from a silicon melt and then cooled from the solidification temperature in accordance with the Czochralski method, the process comprising:
controlling a growth velocity, v, and an average axial temperature gradient, G₀, during the growth of the constant diameter portion of the crystal over the temperature range from solidification to a temperature of no less than about 1325° C., to cause the formation of an generally cylindrical region in which vacancies, upon cooling of the ingot from the solidification temperature, are the predominant intrinsic point defect and the generally cylindrical region has a width equal to that of constant diameter portion of the ingot.

41. The process as set forth in claim 40 wherein the generally cylindrical region has a length of at least about 40% of the length of the constant diameter portion of the ingot.

42. The process as set forth in claim 40 wherein the generally cylindrical region has a length of at least about 60% of the length of the constant diameter portion of the ingot.

43. The process as set forth in claim 40 wherein the generally cylindrical region has a length of at least about 80% of the length of the constant diameter portion of the ingot.

44. The process as set forth in claim 40 wherein the generally cylindrical region has a length of about 100% of the length of the constant diameter portion of the ingot.

45. The process as set forth in claim 40 wherein the radius of the constant diameter portion of the ingot is about 100 mm.

46. The process as set forth in claim 40 wherein the radius of the constant diameter portion of the ingot is about 150 mm.

47. The process as set forth in claim 40 wherein the generally cylindrical region has a concentration of oxygen of up to about 18 ppma.

48. The process as set forth in claim 40 wherein the generally cylindrical region has a concentration of oxygen of about 10 ppma to about 16 ppma.

49. The process as set forth in claim 40 wherein the growth velocity, v, and the average axial temperature gradient, G₀, are controlled such that a ratio, v/G₀, at the circumferential edge, v/G₀(r_{ce}), ranges in value from about 1.0 to about 3.0 times the critical value of v/G₀.

50. The process as set forth in claim 40 wherein the growth velocity, v, and the average axial temperature gradient, G₀, are controlled such that a ratio, v/G₀, at the circumferential edge, v/G₀(r_{ce}), ranges in value from about 2.0 to about 2.75 times the critical value of v/G₀.

51. The process as set forth in claim 40 wherein the growth velocity, v, and the average axial temperature gradient, G₀, are controlled such that a ratio, v/G₀, at the circumferential edge, v/G₀(r_{ce}), ranges in value from about 2.1 to about 2.6 times the critical value of v/G₀.

52. The process as set forth in claim 40 wherein the crystal has a nominal diameter of about 150 mm and wherein the growth velocity, v, and the average axial temperature gradient, G₀, are controlled such that a ratio, v/G₀, at the circumferential edge, v/G₀ (r_{ce}), is greater than about 4.2×10⁻⁵ cm²/sK.

53. The process as set forth in claim 40 wherein the ingot comprises dopant atoms selected from the group consisting of boron, aluminum, gallium and indium.

54. The process as set forth in claim 40 wherein the ingot comprises boron atoms.

55. The process as set forth in claim 54 wherein the concentration of boron atoms is about 1×10¹⁹ atoms/cm³ to about 3×10¹⁹ atoms/cm³.
